(19) United States
(12) Patent Application Publication
(10) Pub. No.: US 2025/0385703 A1
(43) Pub. Date: Dec. 18, 2025

(54) SYSTEM AND METHODS FOR CONTROLLING FILTER BANK DEVICE

(71) Applicant: Qorvo US, Inc., Greensboro, NC (US)

(72) Inventors: Paul E. Gorday, Palm Beach, FL (US); Gangadhar Burra, Fremont, CA (US); Kevin Kobayashi, Redondo Beach, CA (US); Charles Forrest Campbell, Dallas, TX (US)

(21) Appl. No.: 19/201,590

(22) Filed: May 7, 2025

Related U.S. Application Data
(60) Provisional application No. 63/660,385, filed on Jun. 14, 2024.

(51) Int. Cl. H04B 1/16; H03L 7/04; H04B 1/7093

(52) U.S. Cl. CPC H04B 1/1607; H03L 7/04; H04B 1/7093; H04B 2001/70935

(57) ABSTRACT

A frequency control device is provided. The frequency control device is configured to receive a plurality of environmental state parameters of an environment; and convert the plurality of environmental state parameters to an environmental state vector. The frequency control device is also configured to receive the environmental state vector and a search request from a filter bank device communicatively coupled to the frequency control device, the search request being triggered by a power level of a radio frequency (RF) signal at an input or an output of the filter bank device; and determine, based on the environmental state vector, a control signal corresponding to a configuration of disabling a selected filter in a plurality of filters in the filter bank device to attenuate the RF signal in the input of the filter bank device.

### RELATED PATENT APPLICATION(S)

The present application claims the benefit of U.S. Provisional Application No. 63/660,385, entitled “SYSTEM AND METHODS FOR CONTROLLING FILTER BANK DEVICE” and filed on Jun. 14, 2024, which is hereby incorporated by reference in its entirety.

### FIELD OF THE DISCLOSURE

The present disclosure relates to frequency control and, in particular, to systems and methods for frequency control of a filter bank device.

### BACKGROUND

An intrinsically switched multiplexing filter (ISM) has a plurality of filters coupled between an antenna and receiver ports. Each filter has its respective frequency passbands. The ISM has digital control inputs that allow individual passbands of the ISM to be switched on or off, thereby selectively attenuating strong signals at specific frequencies t. Given its relatively low insertion loss, flat passband, and steep transition bands, an ISM can be used to limit the power of strong signals. For example, an ISM can be used prior to a low noise amplifier (LNA) in the receiver front-end to attenuate strong signals at the input of the LNA.

However, finding the correct filter(s) in the ISM to attenuate a strong signal can be time consuming. Thus, methods and systems to timely and accurately locate the filter(s) is desired.

### SUMMARY

Embodiments of the disclosure provide a frequency control device. The frequency control device is configured to receive a plurality of environmental state parameters of an environment; and convert the plurality of environmental state parameters to an environmental state vector. The frequency control device is also configured to receive the environmental state vector and a search request from a filter bank device communicatively coupled to the frequency control device, the search request being triggered by a power level of a radio frequency (RF) signal at an input or an output of the filter bank device; and determine, based on the environmental state vector, a control signal corresponding to a configuration of disabling a selected filter in a plurality of filters in the filter bank device to attenuate the RF signal in the input of the filter bank device.

In some embodiments, the determining of the control signal includes: selecting a filter-searching algorithm from a plurality of filter-searching algorithms based on the environmental state vector; applying a search control signal corresponding to a potential configuration of the filter bank device according to the selected filter-searching algorithm; and in response to a power level of an output of the filter bank device falls below a predetermined value, determining the search control signal to be the control signal.

In some embodiments, the frequency control device further includes a power sensor that detects the power level of the output or the input of the filter bank device.

In some embodiments, the filter bank device comprises an intrinsically switched multiplexing filter.

In some embodiments, the plurality of environmental state parameters comprise one or more of: an input power level of the filter bank device, an output power level of the filter bank device, a number of enabled filters in the filter bank device, a number of disabled filters in the filter bank device, a current of a low-noise amplifier (LNA) coupled to an output of the filter bank device, a voltage of the LNA, a bias configuration of the LNA, an integrated power level of a baseband detector coupled to an output of the LNA, a DC power level of the baseband detector, a time domain statistic value of the baseband detector, or a frequency domain statistic value of the baseband detector.

In some embodiments, the frequency control device further includes a plurality of sensors that measure the plurality of environmental state parameters.

In some embodiments, the frequency control device includes a reinforcement learning (RL) model stored in a memory.

In some embodiments, the RL model is pre-trained.

In some embodiments, the search request is received after converting the plurality of environmental state parameters to the environmental state vector.

In some embodiments, the search request is received before converting the plurality of environmental state parameters to the environmental state vector.

In some embodiments, a training of the RL model includes: determining, by the RL model, an action that comprises selecting a filter-searching algorithm from a plurality of filter-searching algorithms, based on a policy and the environmental state vector; executing the action by performing the selected filter-searching algorithm that incurs a reward; receiving the reward based on the action; and updating the policy and a value function based at least on the reward.

In some embodiments, the RL model comprises a neural network (NN) model.

In some embodiments, the policy comprises one of a deterministic function or a stochastic function.

In some embodiments, the value function comprises a set of tabular memory data.

In some embodiments, the updating of the policy and the value function includes: computing a difference between the reward and the value function; and updating the policy and the value function based on the difference.

In some embodiments, the reward includes a combination of: a number of filters enabled when the selected filter-searching algorithm is performed; a number of state values of the filter bank device attempted by the selected filter-searching algorithm; or a penalty value for the selected filter-searching algorithm not finding a state value of the filter bank device that attenuates the power level of an output of the filter bank device below the predetermined value.

Embodiments of the disclosure provide a method for attenuating a signal at an input of a filter bank device having a plurality of frequency passbands. The method includes: receiving, via a data interface, a plurality of environmental state parameters of an environment; converting, by a processor, the plurality of environmental state parameters to an environmental state vector; receiving, by the processor, a search request from the filter bank device, the search request being triggered by a power level at an input or an output of the filter bank device; and determining, by the processor, based on the environmental state vector, a control signal corresponding to a configuration of disabling a selected filter in a plurality of filters in the filter bank device to attenuate a radio frequency (RF) signal in the input of the filter bank device.

In some embodiments, the determining of the control signal includes: selecting, by a reinforcement learning (RL) model, a filter-searching algorithm from a plurality of filter-searching algorithms based on the environmental state vector; applying, by the processor, a search control signal corresponding to a potential configuration of the filter bank device according to the selected filter-searching algorithm; and in response to a power level of an output of the filter bank device falls below a predetermined value, determining, by the processor, the search control signal to be the control signal.

In some embodiments, the plurality of environmental state parameters includes one or more of: an input power level of the filter bank device, an output power level of the filter bank device, a number of enabled filters in the filter bank device, a number of disabled filters in the filter bank device, a current of a low-noise amplifier (LNA) coupled to an output of the filter bank device, a voltage of the LNA, a bias configuration of the LNA, an integrated power level of a baseband detector coupled to an output of the LNA, a DC power level of the baseband detector, a time domain statistic value of the baseband detector, or a frequency domain statistic value of the baseband detector.

Embodiments of the disclosure provide a signal attenuation device, including a filter bank device and a frequency control device communicatively coupled to the filter bank device. The filter bank device includes a plurality of filters corresponding to a plurality of frequency passbands, and is configured to receive a radio frequency (RF) signal. The frequency control device is configured to receive a plurality of environmental state parameters of an environment; convert the plurality of environmental state parameters to an environmental state vector; and determine, based on the environmental state vector, a control signal corresponding to a configuration of disabling a selected filter in a plurality of filters in the filter bank device to attenuate the RF signal in the input of the filter bank device.

In some embodiments, the determining of the control signal includes: selecting a filter-searching algorithm from a plurality of filter-searching algorithms based on the environmental state vector; applying a search control signal corresponding to a potential configuration of the filter bank device according to the selected filter-searching algorithm; and in response to a power level of an output of the filter bank device falls below a predetermined value, determining the search control signal to be the control signal.

In some embodiments, the plurality of environmental state parameters includes one or more of: an input power level of the filter bank device; an output power level of the filter bank device; a number of enabled filters in the filter bank device; a number of disabled filters in the filter bank device; a current of a low-noise amplifier (LNA) coupled to an output of the filter bank device; a voltage of the LNA; a bias configuration of the LNA; an integrated power level of a baseband detector coupled to an output of the LNA; a DC power level of the baseband detector; a time domain statistic value of the baseband detector; or a frequency domain statistic value of the baseband detector.

In some embodiments, the noise reduction device further includes a plurality of sensors for measuring the plurality of environmental state parameters.

In some embodiments, the frequency control device includes a reinforcement learning (RL) model stored in a memory.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIG. 1A illustrates a simplified block diagram of an exemplary signal attenuation device, according to some aspects of the present disclosure.

FIG. 1B illustrates frequency passbands of a plurality of filters in a filter bank module, according to some aspects of the present disclosure.

FIGS. 1C and 1D each illustrates an example of a configuration of the filter bank module corresponding to a respective set of state values, according to some aspects of the present disclosure.

FIGS. 1E and 1F each illustrates sets of state values used in a search algorithm for a configuration of a filter bank module, according to some aspects of the present disclosure.

FIG. 2A illustrates an example of a signal attenuation device, according to some aspects of the present disclosure.

FIG. 2B illustrates an example of an autonomous agent used in a frequency control module of the signal attenuation device, according to some aspects of the present disclosure.

FIG. 3A illustrates a simplified diagram of an exemplary computing device implementing the frequency control module illustrated in FIGS. 1, 2A, and 2B, according to some aspects of the present disclosure.

FIG. 3B illustrates a structure of a neural network model used in an exemplary frequency control module, according to some aspects of the present disclosure.

FIGS. 4A and 4B illustrate flowcharts of exemplary operation of a frequency control module illustrated in FIGS. 1, 2A, and 2B, according to some aspects of the present disclosure.

FIG. 5 illustrates a flowchart of an exemplary method for operating the signal attenuation device, according to some aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein. Additionally, like reference numerals denote like features throughout specification and drawings.

It should be appreciated that the blocks in each signaling diagram or flowchart and combinations of the signaling diagrams or flowcharts may be performed by computer program instructions. Since the computer program instructions may be equipped in a processor of a general-use computer, a special-use computer or other programmable data processing devices, the instructions executed through a processor of a computer or other programmable data processing devices generate means for performing the functions described in connection with a block(s) of each signaling diagram or flowchart. Since the computer program instructions may be stored in a computer-available or computer-readable memory that may be oriented to a computer or other programmable data processing devices to implement a function in a specified manner, the instructions stored in the computer-available or computer-readable memory may produce a product including an instruction for performing the functions described in connection with a block(s) in each signaling diagram or flowchart. Since the computer program instructions may be equipped in a computer or other programmable data processing devices, instructions that generate a process executed by a computer as a series of operational steps are performed by the computer or other programmable data processing devices and operate the computer or other programmable data processing devices may provide steps for executing the functions described in connection with a block(s) in each signaling diagram or flowchart.

Each block may represent a module, segment, or part of a code including one or more executable instructions for executing a specified logical function(s). Further, it should also be noted that in some replacement execution examples, the functions mentioned in the blocks may occur in different orders. For example, two blocks that are consecutively shown may be performed substantially simultaneously or in a reverse order depending on corresponding functions.

In this disclosure, a “strong signal” refers to a radio frequency (RF) signal of which the power intensity is undesirably high such that the strong signal may cause damage in an electronic device (e.g., a low-noise amplifier or LNA) that receives the strong signal as an input, or cause the electronic device to function in an undesirable regime/mode. In this disclosure, a strong signal may be determined if the power intensity is higher than a predetermined value/level.

An intrinsically switched multiplexing filter (ISM) has input and output power detectors to help determine when strong signals have been successfully attenuated. Currently, several algorithms have been proposed that iteratively search through an ISM's possible configuration(s) to find one that attenuates the strong signals while passing as much of the remaining spectrum as possible. The cumulative unattenuated bandwidth and the search time of the algorithm are two key performance indicators (KPIs).

Search algorithms generally achieve the goal of maximizing cumulative bandwidth. However, search time can vary significantly depending on the radio frequency (RF) signal conditions. Efforts at improving search time have focused on search behavior within an individual algorithm. However, depending on the algorithm, it can take an undesirably long time to find the desired configuration.

Embodiments of the present provide a frequency control device, upon detecting a strong signal received by an ISM, automatically searches for the configuration of the ISM to attenuate the signal with optimized search time and cumulative bandwidth. Specifically, the frequency control device automatically selects a search algorithm based on the environmental condition, and perform the selected search algorithm by applying control signals on the ISM until the strong signal is attenuated. The control signals each corresponds to a different configuration of the ISM, and are applied according to a sequence determined by the search algorithm.

The frequency control device contains an autonomous agent, which includes a reinforcement learning (RL) model implemented on a chip. The RL model may be a pre-trained model (e.g., in deployment stage) or is in training/learning stage. The autonomous agent, based on its training, can automatically output an action of selecting/predicting a search algorithm for an ISM based on the observed environmental condition of the autonomous agent when the undesirable signal is detected at the ISM. The frequency control device then performs the selected search algorithm and generates a respective control signal that corresponds to each configuration of the ISM determined by the algorithm. Specifically, the selected search algorithm may correspond to a sequence of sets of state values that correspond to enabling/disabling certain filters of the ISM.

In this disclosure, a set of search algorithms for finding the ISM filter configuration state that attenuates a strong signal and maximizes cumulative bandwidth are used in the training and deployment stages of the autonomous agent. The average search time of each search algorithm is optimal for specific RF signal conditions. The autonomous agent is trained by updating its policy and value functions based on a reward, which is related to the search time and cumulative bandwidth corresponding to the search algorithm at a specific RF signal condition (e.g., environmental condition). At training stage, the autonomous agent observes an environment state vector that characterizes the RF signal conditions, evaluates a policy to select a search algorithm based on the state vector, receives a reward for the algorithm selection, and updates policy and value functions using the reward.

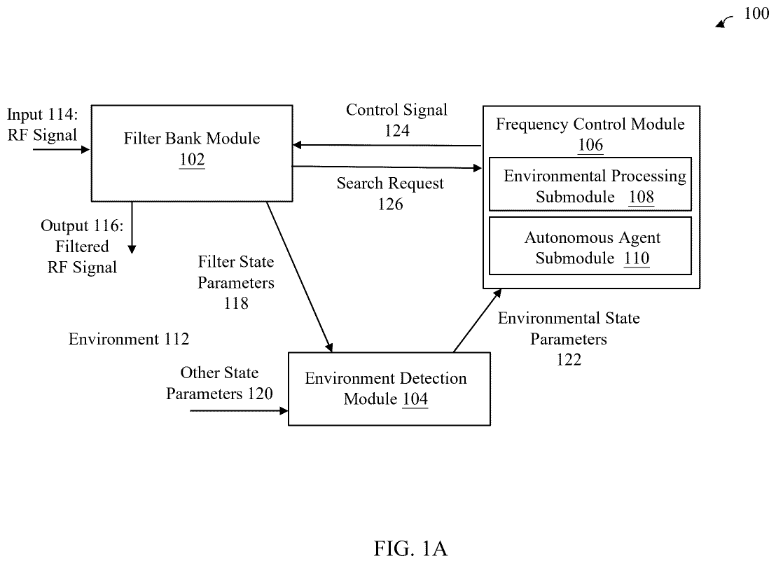

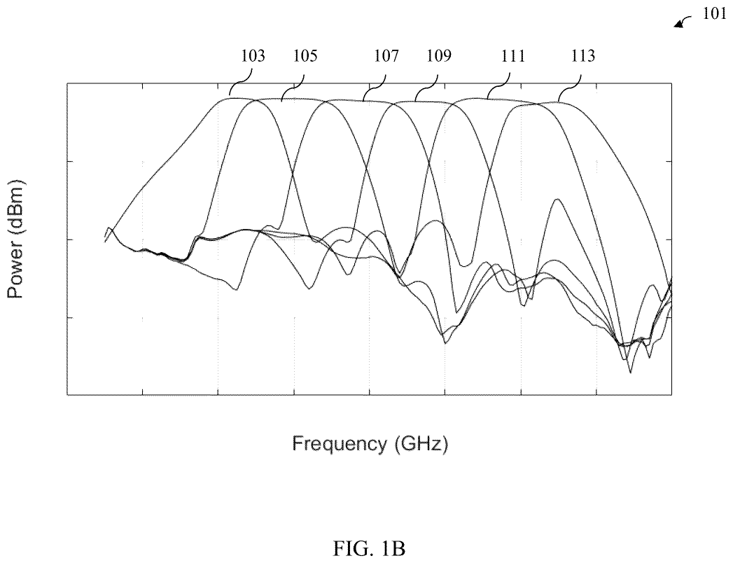

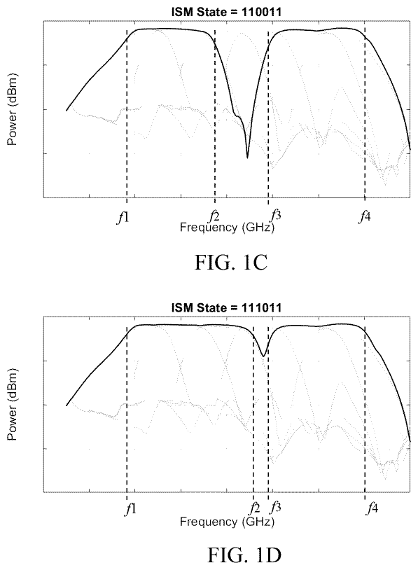

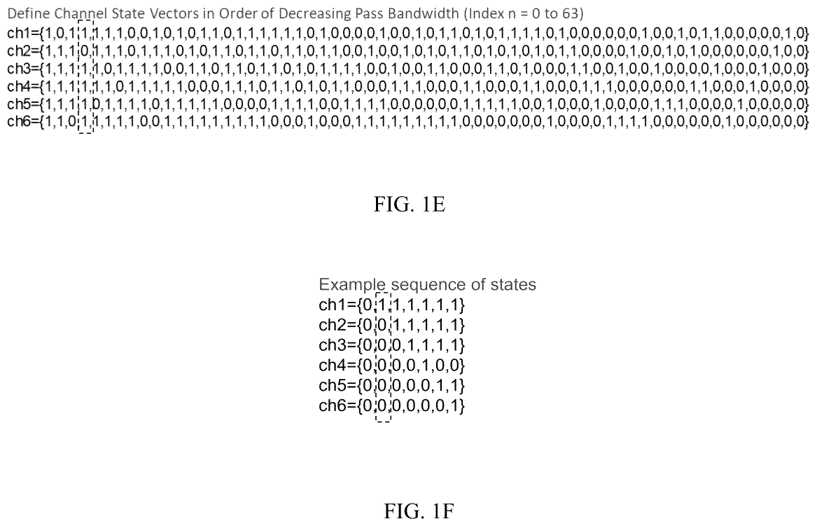

FIG. 1A illustrates a signal attenuation device 100, according to some embodiments of the present disclosure. Signal attenuation device 100 may be coupled to the input of a low noise amplifier (LNA) to attenuate the power of a strong signal at the LNA input. Signal attenuation device 100 may receive a radio frequency (RF) signal (e.g., containing a strong signal) in an input, and may output a spectrum with the frequency of the strong signal attenuated. In some embodiments, signal attenuation device 100 includes a filter bank module 102, an environment detection module 104 communicatively coupled to filter bank module 102, and a frequency control module 106 communicatively coupled to environment detection module 104 and filter bank module 102.

Filter bank module 102 may include a plurality of filters, each having a respective frequency passband. In some embodiments, the output of filter bank module 102 may be communicatively coupled to a LNA (not shown in FIG. 1A). In operation, filter bank module 102 may receive an input 114 including a RF signal, and may send a search request 126 to frequency control module 106. In some embodiments, the RF signal includes a strong signal that is undesirably high to the LNA. In response to receiving search request 126, frequency control module 106 may send one or more control signals 124 to set filter bank module 102 to different configurations according to a search algorithm, attempting to attenuate the strong signal. When the strong signal is attenuated, an output 116 of filter bank module 102 reaches a sufficiently low power level, and the configuration (or control signal 124) for attenuating the strong signal is found. In some embodiments, the configuration of filter bank module 102 that attenuates the strong signal includes enabling and/or disabling one or more filters in filter bank module 102. The frequency band(s) of the disabled filter(s) may overlap with the frequency of the strong signal in input 114, such that the strong signal is attenuated. Filter bank module 102 may then generate an output 116 that includes a filtered RF signal, with the strong signal attenuated. Output 116 may then be used as an input for other devices such as the LNA.

Frequency control module 106 may receive a set of environmental parameters 122 representing the state of an environment 112 that frequency control module 106 is located in, automatically select a search algorithm based on set of environmental parameters 122, and output control signals 124 according to the selected search algorithm. Set of environmental state parameters 122 may include various parameters reflecting the condition of environment 112, which includes filter state parameters 118 and other state parameters 120. In some embodiments, filter state parameters 118 include any suitable parameters of filter bank module 102, such as power levels, currents, voltages, frequencies, bandwidths, and/or temperatures, etc. In some embodiments, other state parameters include any suitable parameters of the electronic devices communicatively coupled to filter bank module 102. These parameters may include power levels, currents, voltages, frequencies, bandwidths, and/or temperatures, etc. of these electronic devices. In some embodiments, environment detection module 104 may include various sensors communicatively coupled to filter bank module 102 and other electronic devices in environment 112 to obtain/measure filter state parameters 118 and other state parameters 120. The obtained/measured parameters may be transmitted to frequency control module 106 as set of environmental state parameters 122, which are observed environmental state parameters to frequency control module 106. In some embodiments, a power meter/sensor may be coupled to input 114 and/or output 116 of filter bank module 102 and frequency control module 106, and may trigger search request 126 to frequency control module 106 when the input power level and/or output power level is above a predetermined threshold value. In some embodiments, a power meter/sensor may be coupled to output 116 of filter bank module 102 and frequency control module 106, and may measure the power level of output 116. Frequency control module 106 may determine whether the strong signal is attenuated based on whether the power level at output 116 falls below a predetermined threshold value.

Frequency control module 106 may include an environmental processing submodule 108 and an autonomous agent submodule 110 communicatively coupled to environmental processing submodule 108. Environmental processing submodule 108 may extract features from environmental state parameters 122 and convert set of environmental state parameters 122 to an environmental state vector. Autonomous agent submodule 110 may include RL model that is configured to generate one or more control signals 124 based on the environmental state vector. In some embodiments, the environmental state vector is fed to the RL model to generate an output action of a predicted/selected search algorithm in response to the environmental state vector. Autonomous agent submodule 110 may then execute the action by performing the selected search algorithm and applying control signals 124 accordingly. Autonomous agent submodule 110 may keep applying control signals 124 corresponding to different configurations of filter bank module 102 until the strong signal is attenuated.

In some embodiments, filter bank module 102 includes an intrinsically switched multiplexing filter (ISM), which includes a plurality of filters, each having a respective frequency passband. The structures, functions, and operations of an ISM is described in U.S. Pat. No. 11,245,427 B1, which is incorporated herein by its entirety, and the detailed description is omitted herein. FIG. 1B shows a plot 101 of the frequency passbands of filters in an ISM. As an example, the ISM may include six filters (or channels), corresponding to six respective frequency passbands 103, 105, 107, 109, 111, and 113. Each of the frequency passbands 103-113 may cover a respective range of frequencies. Enabling (or turning on) a specific frequency passband allows a frequency in the corresponding range to pass the ISM, and disabling (or turning off) a specific frequency passband attenuates a frequency in the corresponding frequency range. The state value corresponding to an enabled filter is denoted as “1”,and the state value corresponding to a disabled filter is denoted as “0”. The combined state values of all filters may reflect a configuration or state of the ISM. In other words, a configuration of the ISM includes a combination of the state values of all filters.

As examples, FIG. 1C shows an ISM state/configuration of “110011” with filters 103, 105, 111, and 113 enabled (e.g., each represented by a state value “1”) and filters 107 and 109 disabled (e.g., each represented by a state value “0”); and FIG. 1D shows an ISM state/configuration of “111011” with filters 103, 105, 107, 111, and 113 enabled (e.g., each represented by a state value “1”) and filter 109 disabled (e.g., represented by a state value “0”).

FIGS. 1E and 1F show a plurality of state values indicating the different configurations of an ISM. Each state value indicates the enable (turn on) or disable (turn off) states of the respective filter (channel or “chn,” n=1, 2, . . . , 6) in the ISM. When a strong signal is received by the ISM, one or more sets of state values may correspond to the configuration of the ISM that attenuates the strong signal. For example, each configuration correspond to a respective control signal (e.g., 124). When the strong signal is attenuated, the output power of the ISM may become sufficiently low. For example, if the output power of the ISM falls below a threshold value following the disabling of filter 103 with all other filters staying enabled, it is determined that the configuration “011111” of the ISM can attenuate the strong signal. In operation, frequency control module 106 may generate a control signal (e.g., 124) that corresponds to the configuration/state “011111” to disable filter 103 while keeping all other filters enabled.

The state values of the filters can be used by a search algorithm to determine the filter(s) to disable (e.g., to attenuate a strong signal), and enable (e.g., to pass a signal of a desired power intensity, e.g., below the predetermined threshold power value). When the ISM receives a strong signal, frequency control module 106 may select and perform a search algorithm that searches the configurations of the ISM until the output power of the ISM falls below the predetermined threshold power value. In operation, upon receiving input 114, filter bank module 102 may send a search request 126 to frequency control module 106, which selects and performs a search algorithm. For each configuration the search algorithm attempts, frequency control module 106 may output a corresponding control signal (e.g., 124) to the ISM and measure the power level of output 116 of the ISM. In some embodiments, frequency control module 106 may continue to output a control signal until the power level of output 116 falls below a predetermined value. Frequency control module 106 may then maintain the last control signal, which corresponds to a specific configuration (e.g., state values) of all the filters.

FIG. 1E shows 64 (e.g., 2⁶) configurations of an ISM with 6 filters 103, . . . , 113. The 64 configurations are represented by 64 sets of state values (ch1, ch2, ch3, ch4, ch5, ch6), while ch6, . . . , ch1 respectively represent filter 103, . . . , 113. A configuration “111101” is denoted in a dashed box as an example. The 2⁶ (or 2ⁿ for n filters) configurations of an ISM may be used in a first search algorithm to find the filter(s) to disable. The first algorithm may be referred to as “ordered search.” In ordered search, all possible configurations (e.g., 2⁶) of the ISM are searched in a specific order until the ISM output power falls below an acceptable predetermined threshold. For example, the configuration state 111011 represents an ISM having six filters in which the fourth filter (e.g., filter 109) is disabled. The sequence of configuration states in FIG. 1E is searched from left to right, where state 1111111 (no attenuation) is attempted first, followed by all combinations of one band disabled, and then all combinations of two bands disabled, and so on. This sequence may assure that the first configuration that satisfies the output power threshold will have maximum cumulative bandwidth. If input 114 includes a strong signal, the search time may be as short as two steps, but if input 114 includes multiple strong signals, the search time may be as long as 64 steps.

FIG. 1F shows 7 (e.g., (6+1)) configurations of an ISM with 6 filters 103, . . . , 113. The 7 configurations are represented by 7 sets of state values (ch1, ch2, ch3, ch4, ch5, ch6), while ch6, . . . , ch1 respectively represent filter 103, . . . , 113. A configuration “100000” is denoted in a dashed box as an example. The 7 (or (n+1) for n filters) configurations of an ISM may be used in a second search algorithm to find the filter(s) to disable. The second search algorithm may be referred to as “successive approximation”. Using the second search algorithm, the ISM configuration may be determined one bit at a time. Initially, all filters are disabled. As an example, the second algorithm may begin with ch1 (e.g., filter 113), which corresponds to the least significant bit in the ISM state. If the ISM output power is below the desired predetermined threshold value, then ch1 (filter 113) is enabled (i.e., ISM configuration state=000001). If the resulting ISM output power is below the target threshold, then ch1 remains enabled, otherwise ch1 is disabled and the algorithm moves to the next filter (e.g., filter 111) and repeats the test. FIG. 1F shows a sequence of ISM configurations for the case where disabling ch4 (e.g., filter 107) is sufficient to achieve the desired ISM output power. The algorithm search time is equal to one more than the number of filters. This may be an advantage in congested RF signal conditions because the worst-case search time is bounded. However, the best search time of the second search algorithm is also bounded by the same amount. Furthermore, it can be shown that the second search algorithm may not guarantee maximum cumulative bandwidth.

The third search algorithm may be referred to as a subset ordered search. Here the algorithm may attempt a small subset of ISM configurations in the order determined by the relative frequency of their occurrence. The subset may contain as few as one or two configurations. If the RF signal conditions fall into a small set of possible configurations, then this approach may potentially achieve the fastest average search time.

As described above, the search time to find a configuration of the ISM can vary drastically depending on the RF signal conditions, or environmental conditions of the ISM. It is thus desirable that frequency control module 106 finds the configuration to attenuate the strong signal in a desirably short period of time under various, e.g., all, RF signal conditions.

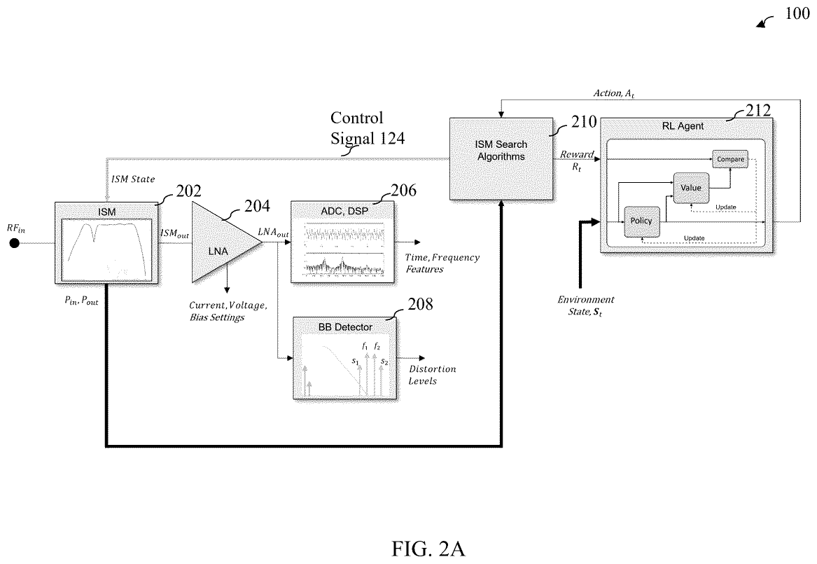

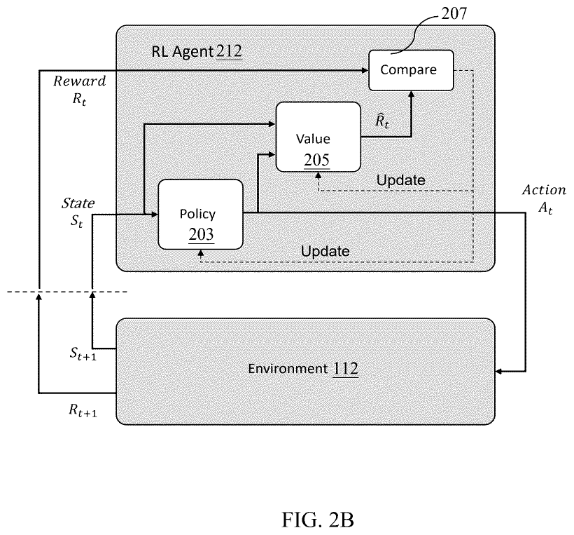

FIG. 2A illustrates an example of signal attenuation device 100, according to some embodiments of the present disclosure. Frequency control module 106 may include an autonomous agent 212 (“RL Agent”) configured to select a search algorithm from a plurality of search algorithms 210 (“ISM Search Algorithms”) based on the environmental conditions of a ISM 202. Frequency control module 106 may perform the selected search algorithm to find the configuration of ISM 202 that can attenuate a RF signal (RFin) received by ISM 202. In some embodiments, frequency control module 106 outputs a respective control signal 124 corresponding to each configuration of ISM 202 according to the selected search algorithm until RFin is attenuated. The control signal 124 that attenuates RFin may correspond to a configuration of ISM 202 with certain filters disabled (and/or enabled). Autonomous agent 212 may be similar to autonomous agent submodule 110, and may include a RL model. In some embodiments, autonomous agent 212 may be implemented on a chip. Autonomous agent 212 may interact with its environment 112 which may include various devices such as an LNA 204, a signal processing module 206, and/or a baseband (BB) detector 208. The environmental conditions of ISM 202, reflected in a set of environmental state parameters (e.g., 122) may include any suitable conditions occurring around the time RFin is received. For example, the environmental conditions may include various operation parameters of ISM 202, LNA 204, signal processing module 206, and/or baseband detector 208. In some embodiments, signal processing module 206 includes any suitable signal processing devices such as an analog-to-digital converter (ADC), a digital signal processor (DSP), etc.

FIG. 2B shows autonomous agent 212 interacting with its environment 112 to output an action, according to some embodiments of the present disclosure. Autonomous agent 212 may include a RL model implemented as a combination of hardware and software on a chip. In some embodiments, autonomous agent 212 includes a neural network model. As shown in FIGS. 2A and 2B, autonomous agent 212 may output an action (e.g., a prediction/selection of a search algorithm) from a plurality of ISM search algorithms stored in the chip based on a policy function 203 and an input of a set of observed environmental state parameters received from environment 112. In training stage, autonomous agent 212 may train to optimize policy function 203 and a value function 205 with a compare module 207.

Autonomous agent 212 may include a RL model that generates an action (e.g., a selection/prediction of a search algorithm) in response to a set of observed environmental state parameters (e.g., 122) of environment 112. The environmental state parameters correspond to a environmental state vector. At each timestamp, autonomous agent 212 may execute an action Aₜ (outputted by the RL model) in environment 112. In some embodiments, autonomous agent 212 executes/performs the selected search algorithm. The action may may change the environmental state vector Sₜ of environment 112 to a new environmental state vector Sₜ₊₁ and causes a reward Rₜ. In some embodiments, at training stage, autonomous agent 202 receives reward Rₜ indicating how good or bad the previous chosen action Aₜ₋₁ was, and may update its policy 203 and/or value function 205 to maximize the accumulative reward (return) overtime.

Autonomous agent 212 may be fed with an environmental state vector converted from a set of observed environmental state parameters (e.g., 122), as for predicting the search algorithm. In some embodiments, the environmental state vector includes a high-dimensional set of features from the ISM and other radio components such as LNA 204, signal processing module 206, and/or baseband detector 208. In some embodiments, policy function 203 may be a neural network (NN) that is trained to infer RF signal conditions from the complex environmental state vector and select an action that maximizes future rewards. Value function 205 may also include a NN that is trained to predict future rewards for each state and action combination.

The set of observed environmental state parameters may be received via an interface connection. In various embodiments, the interface connection is communicatively coupled to a plurality of sensors (e.g., environment detection module 104) that are configured to measure the environmental state parameters from various radio components (e.g., ISM 202, LNA 204, signal processing module 206, and/or BB detector 208) in environment 112. For example, the sensors may include one or more current sensors, one or more voltage sensors, one or more power sensors, etc. In some embodiments, example features extracted from the environmental state parameters may include one or more of the following (either instantaneous or averaged over a recent period of time):

ISM features: the number of enabled/disabled filters, the input power level, and/or output power level of the ISM.

LNA features: currents (I_{dd}, I_{g1}, I_{g2}), voltages (V_{dd}, V_{g1}, V_{g2}), and/or the bias configurations.

Distortion level features: baseband (BB) detector integrated power, and/or baseband detector DC power.

Baseband (BB) time/frequency features: time domain statistics (root mean square (RMS), level crossing rate, autocorrelation coefficients), frequency domain statistics (FFT level crossing rate, occupied bandwidth).

In some embodiments, a lower-dimensional set of features that efficiently represent the RF signal conditions relevant to selecting the best search algorithm is used. The lower-dimensional set of features may allow the value function (e.g., 205) to be implemented using simple tabular memory (e.g., a set of tabular memory data), and the policy (e.g., 203) may be a simple stochastic function like the epsilon-greedy function. An example one-dimensional environmental state vector is the average number of enabled or disabled filter passbands during a recent period. Similarly, the number of baseband Fast Fourier Transform (FFT) bins above a threshold may be used. The one dimensional environment state vector provides an indication of a spectral congestion and may be sufficient to determine the best search algorithm for the present RF signal conditions.

In some embodiments, assume D represents the average number of disabled filters over a recent time period (or over some recent number of reconfiguration events), and Pin represents the current ISM input power. An example of a one-dimensional state vector may include S=[D], and an example of a two-dimensional state vector may include S=[D, Pin]. In some embodiments, a more complex state vector may use the number of disabled filters for the N most recent reconfiguration events, S=[d(n−1), d(n−2), . . . , d(n−N)]. In some embodiments, if there is a temporal pattern to the interference, the autonomous agent 212 may learn to choose the best state search pattern based on the expected next event.

Autonomous agent 212 may output an action Aₜ that is the selection of a search algorithm based on policy 203. Policy 203 may be a mapping between all possible environmental states S to probabilities P of performing any possible action from that state S. In some embodiments, policy 203 is deterministic, such that policy 203 may choose the action that is expected to produce the highest value. In some embodiments, policy 203 is stochastic, where policy 203 may randomly select from all actions according to a probability distribution. Stochastic policies are needed when autonomous agent 212 is intended to adapt its behavior in the field. Using a probability distribution, autonomous agent 212 may select the action expected to produce the highest value most of the time and selects the other actions a small fraction of the time in order to explore and adapt to changing conditions. In some embodiments, policy 203 may choose from a plurality of possible actions, each corresponding to a search algorithm. For example, the possible actions may correspond to selection of a respective one of the first-third search algorithms described in this disclosure.

Value function 205 may estimate the future rewards associated with each action. Value function 205 may be a state-value function or an action-value function. The state-value function may be a mapping for each environmental state vector to the cumulative expected reward that autononmous agent 212 may receive if autonomous agent 212 were initially place at that state following policy 203. Action-value function is a mapping from each environment state vector and each possible agent action to the espected reward that autonomous agent 212 would receive if autonomous agent 212 would initially placed at the state and had to take that action following policy 203. In some embodiments, value function 205 is a function of the environmental state vector. In some embodiments, value function 205 is a memory of past rewards and can be implemented using tabular memory data or parametric memory data (e.g., memory data stored in weights of an approximating function such as a polynomial or neural network).

In some embodiments, reward is structured such that actions taken by autonomous agent 212 to maximize the reward achieve the desired system objectives. For example, search time and/or cumulative bandwidth may be part of the reward. In some embodiments, reward R is constructed as R=N_{ISM}−kT_{search}−P_{search}. The integer N_{ISM} represents the number of filter passbands enabled when the search algorithm is finished, and it may represent unattenuated cumulative bandwidth. The integer T_{search} represents the number of ISM configurations attempted during the search, and it represents search time. The real number k is a weighting factor that balances the two key performance indicators (e.g., cumulative unattenuated bandwidth and the algorithm search time). For example, if k=1/Tₛₐ, where Tₛₐ is the number of ISM configurations attempted for the successive approximation algorithm (e.g., Tₛₐ=7 in FIG. 1F), then a loss of one filter passband is equivalent to a loss of Tₛₐ steps of search time. In other words, if the ordered search outperforms successive approximation by one filter passband, autonomous agent 212 may be allowed up to twice the search time. Other values of k could be used to adjust this tradeoff. The last term in the reward, P_{search}, is an optional penalty applied when the search algorithm is unable to find an acceptable ISM configuration. This may be helpful with the subset ordered search algorithm (e.g., the third search algorithm) to indicate when its subset of states is not valid.

In practice, policy 203 and value function 205 may be trained in advance using simulated or collected data from/representing environment 112. At training stage, the error between value function 205 and received reward Rₜ may be used to drive updates to policy 203 and value function 205. In some embodiments, upon receiving RFin, autonomous agent 212 obtains an environmental state vector Sₜ corresponding to a set of observed environmental state parameters. Autonomous agent 203 (or the RL model) may output an action Aₜ from policy 203 based on the environmental state vector Sₜ, where the action Aₜ corresponds to the selection of a search algorithm from a plurality of algorithms. Autonomous agent 203 may then execute the action by performing the selected search algorithm. Each time a configuration is attempted according to the search algorithm, autonomous agent 203 may generate a corresponding control signal 124 and apply the control signal 124 on ISM 202. When control signal 124 causes ISM 202 to attenuate RFin, autonomous agent 203 may stop the search algorithm and maintain the control signal 124.

At training stage, policy 203 may optimize to maximize the total reward over time. At time t, when fed with an environmental state vector Sₜ, converted from a set of environmental state parameters, policy 203 may output an action Aₜ from a plurality of possible actions. In some embodiments, the possible actions include the selection of a plurality of different search algorithms (e.g., first search algorithm, second search algorithm, and/or third search algorithm). Meanwhile, environmental state vector Sₜ and action Aₜ may be fed into value function 205 to generate a value \hat{R}ₜ, which is further fed to compare module 207 together with reward Rₜ from environment 112. The difference between Rₜ and \hat{R}ₜ may be fed back to policy 203 to update policy 203 for time (t+1). Autonomous agent 212 may execute action Aₜ by performing the selected search algorithm. Autonomous agent 212 may accordingly generate control signal 124 corresponding to each searched configuration according to the selected search algorithm, and applied control signal 124 on the ISM 202 to disable/enable certain filter(s). When the power level of the output of ISM 202 falls below a predetermined value, autonomous agent 212 may determine the strong signal is attenuated at the corresponding configuration. Autonomous agent 212 may stop performing the search algorithm. In some embodiments, metrics such as search time, and/or cumulative bandwidth are recorded to compute its reward Rₜ and update policy 203 and/or value function 205. In some embodiments, the execution of Aₜ may cause change in environment 112, which may correspond to updated environmental state vector and reward, e.g., Sₜ₊₁ and Rₜ₊₁ for time (t+1).

In some embodiments, policy 203 and value function 205 may be pre-trained and unchanged during operation. In some embodiments, continued updates/learning to policy 203 and value function 205 may be performed in a non-stationary environment. For example, autonomous agent 212 may have a learning mode/stage and a deployment mode/stage. In the learning mode, autonomous agent 212 may continue to update policy 203 and value function 205 in operation. In deployment mode, policy 203 and value function 205 stay unchanged.

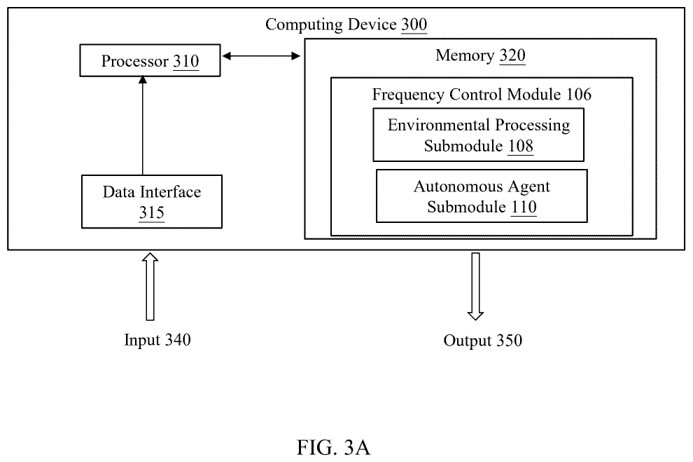

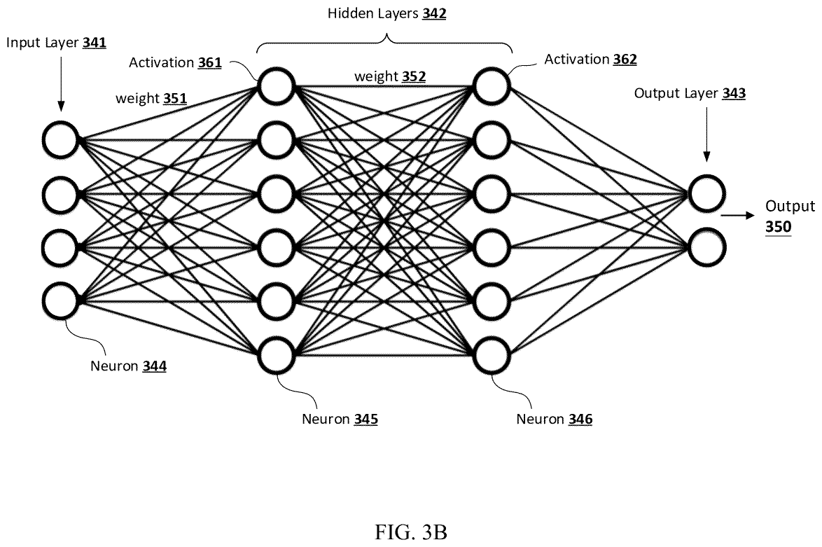

FIG. 3A is a simplified diagram illustrating a computing device 300 implementing the frequency control module 106 described in FIGS. 1, 2A, and 2B, according to one embodiment described herein. As shown in FIG. 3A, computing device 300 includes a processor 310 coupled to memory 320. Operations of computing device 300 is controlled by processor 310. Although computing device 300 is shown with only one processor 310, it is understood that processor 310 may be representative of one or more central processing units, multi-core processors, microprocessors, microcontrollers, digital signal processors, field programmable gate arrays (FPGAs), application specific integrated circuits (ASICs), graphics processing units (GPUs) and/or the like in computing device 300. Computing device 300 may be implemented as a stand-alone subsystem, as a board added to a computing device, and/or as a virtual machine.

Memory 320 may be used to store software executed by computing device 300 and/or one or more data structures used during operation of computing device 300. Memory 320 may include one or more types of machine-readable media. Some common forms of machine-readable media may include floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, and/or any other medium from which a processor or computer is adapted to read.

Processor 310 and/or memory 320 may be arranged in any suitable physical arrangement. In some embodiments, processor 310 and/or memory 320 may be implemented on a same board, in a same package (e.g., system-in-package), on a same chip (e.g., system-on-chip), and/or the like. In some embodiments, processor 310 and/or memory 320 may include distributed, virtualized, and/or containerized computing resources. Consistent with such embodiments, processor 310 and/or memory 320 may be located in one or more data centers and/or cloud computing facilities.

In some examples, memory 320 may include non-transitory, tangible, machine readable media that includes executable code that when run by one or more processors (e.g., processor 310) may cause the one or more processors to perform the methods described in further detail herein. For example, as shown, memory 320 includes instructions for frequency control module 106 that may be used to implement and/or emulate the systems and models, and/or to implement any of the methods described further herein. Frequency control module 106 may receive input 340 such as a search request (e.g., 126input 114) and/or a set of environmental state parameters (e.g., 122) via the data interface 315 and generate an output 350 which may be the control signal 124.

The data interface 315 may comprise a communication interface, a user interface (such as a voice input interface, a graphical user interface, and/or the like). For example, the computing device 300 may receive the input 340 (such as a search request 126 and/or a set of environmental state parameters 122) from a networked database via a communication interface. Or the computing device 300 may receive the input 340, such as such as a search request 126 and/or a set of environmental state parameters 122, from a user via the user interface.

In some embodiments, the frequency control module 106 is configured to generate a control signal 124 response to a search request, conditioned on a set of environmental state parameters 122. The control signal 124 may disable and/or enable certain filters in the coupled filter bank module 102 (e.g., ISM 202). The frequency control module 103 may include environmental processing submodule 108 and autonomous agent submodule 110.

Environmental processing submodule 108 may be configured to convert a set of environmental state values (e.g., 122) into an environmental state vector Sₜ, which is fed to autonomous agent submodule 110. In various embodiments, based on the application, the environmental state vector may be one-dimensional of multi-dimensional. Autonomous agent submodule 110 may include a RL model. The RL model may output an action of a predicted/selected search algorithm based on the environmental state vector (and a search request, in some embodiments). In some embodiments, the RL model is at deployment mode, and is pre-trained for the operations. In the deployment mode, the policy (e.g., 203) and value function (e.g., 205) stay unchanged. In some embodiments, the RL model is at training stage/mode, and its policy (e.g., 203) and value function (e.g., 205) may continue to update based on the reward it receives.

Some examples of computing devices, such as computing device 300 may include non-transitory, tangible, machine readable media that include executable code that when run by one or more processors (e.g., processor 310) may cause the one or more processors to perform the processes of method. Some common forms of machine-readable media that may include the processes of method are, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, and/or any other medium from which a processor or computer is adapted to read. In some embodiment, computing device 300 includes suitable processing circuitries (or equivalent) to perform corresponding functions such as extracting environmental state and/or operating the RL model. For example, environmental processing submodule 108 and/or autonomous agent submodule 110 may include respective circuits to perform the corresponding functions.

FIG. 3B illustrates a simplified diagram showing a neural network structure that can also be used as part of autonomous agent 110, according to some embodiments of the present disclosure. The neural network comprises a computing system that is built on a collection of connected units or nodes, referred to as neurons (e.g., 344, 345, 346). Neurons are often connected by edges, and an adjustable weight (e.g., 351, 352) is often associated with the edge. The neurons are often aggregated into layers such that different layers may perform different transformations on the respective input and output transformed input data onto the next layer.

For example, the neural network architecture may comprise an input layer 341, one or more hidden layers 342 and an output layer 343. Each layer may comprise a plurality of neurons, and neurons between layers are interconnected according to a specific topology of the neural network topology. The input layer 341 receives the input data (e.g., the environmental state vector). The number of nodes (neurons) in the input layer 341 may be determined by the dimensionality of the input data (e.g., the length of a vector of give an example of the input). Each node in the input layer represents a feature or attribute of the input.

The hidden layers 342 are intermediate layers between the input and output layers of a neural network. It is noted that two hidden layers 342 are shown in FIG. 3B for illustrative purposes only, and any number of hidden layers may be utilized in a neural network structure. Hidden layers 342 may extract and transform the input data through a series of weighted computations and activation functions.

For example, as discussed in FIGS. 1A and 2A, autonomous agent submodule 110 receives an input of an environmental state vector and transforms the input into an output 350 to respectively indicate a prediction of the first search algorithm, the second search algorithm, the third search algorithm, etc. To perform the transformation, each neuron receives input signals, performs a weighted sum of the inputs according to weights assigned to each connection (e.g., 351, 352), and then applies an activation function (e.g., 361, 362, etc.) associated with the respective neuron to the result. The output of the activation function is passed to the next layer of neurons or serves as the final output of the network. The activation function may be the same or different across different layers. Example activation functions include but not limited to Sigmoid, hyperbolic tangent, Rectified Linear Unit (ReLU), Leaky ReLU, Softmax, and/or the like. In this way, after a number of hidden layers, input data received at the input layer 341 is transformed into rather different values indicative data characteristics corresponding to a task that the neural network structure has been designed to perform.

The output layer 343 is the final layer of the neural network structure. It produces the network's output or prediction based on the computations performed in the preceding layers (e.g., 341, 342). The number of nodes in the output layer depends on the nature of the task being addressed. For example, in a binary classification problem, the output layer may consist of a single node representing the probability of belonging to one class. In a multi-class classification problem, the output layer may have multiple nodes, each representing the probability of belonging to a specific class.

In one embodiment, the neural network structure may be implemented by hardware, software and/or a combination thereof. For example, the neural network structure may be implemented and run on various hardware platforms, such as but not limited to CPUs (central processing units), GPUs (graphics processing units), FPGAs (field-programmable gate arrays), Application-Specific Integrated Circuits (ASICs), dedicated AI accelerators like TPUs (tensor processing units), and specialized hardware accelerators designed specifically for the neural network computations described herein, and/or the like. Example specific hardware for neural network structures may include, but not limited to Google Edge TPU, Deep Learning Accelerator (DLA), NVIDIA AI-focused GPUs, and/or the like. The hardware used to implement the neural network structure is specifically configured based on factors such as the complexity of the neural network, the scale of the tasks (e.g., training time, input data scale, size of training dataset, etc.), and the desired performance.

In one embodiment, the neural network structure may be trained by iteratively updating the underlying parameters (e.g., weights 351, 352, etc., bias parameters and/or coefficients in the activation functions 361, 362 associated with neurons) of the neural network based on a loss. For example, during forward propagation, the training data such as feature vectors are fed into the neural network. The data flows through the network's layers 341, 342, with each layer performing computations based on its weights, biases, and activation functions until the output layer 343 produces the network's output 350.

The output generated by the output layer 343 is compared to the expected output (e.g., a “ground-truth”) from the training data, to compute a loss function that measures the discrepancy between the predicted output and the expected output. For example, the loss function may be a cross entropy loss, a mean squared error (MSE) loss, etc. Given the loss, the negative gradient of the loss function is computed with respect to each weight of each layer individually. Such negative gradient is computed one layer at a time, iteratively backward from the last layer 343 to the input layer 341 of the neural network. These gradients quantify the sensitivity of the network's output to changes in the parameters. The chain rule of calculus is applied to efficiently calculate these gradients by propagating the gradients backward from the output layer 343 to the input layer 341.

Parameters of the neural network are updated backwardly from the last layer to the input layer (backpropagating) based on the computed negative gradient using an optimization algorithm to minimize the loss. The backpropagation from the last layer 343 to the input layer 341 may be conducted for a number of training samples in a number of iterative training epochs. In this way, parameters of the neural network may be gradually updated in a direction to result in a lesser or minimized loss, indicating the neural network has been trained to generate a predicted output value closer to the target output value with improved prediction accuracy. Training may continue until a stopping criterion is met, such as reaching a maximum number of epochs or achieving satisfactory performance on the validation data. At this point, the trained network can be used to make predictions on new, unseen data, such the prediction of a first search algorithm, a second search algorithm, or a third search algorithm.

Therefore, the training process transforms the neural network into an “updated” trained neural network with updated parameters such as weights, activation functions, and biases.

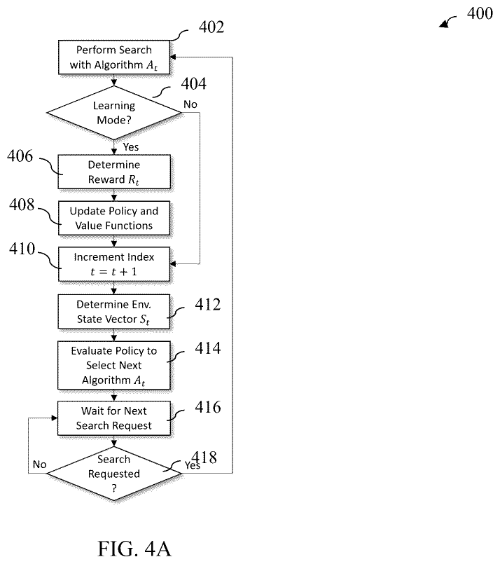

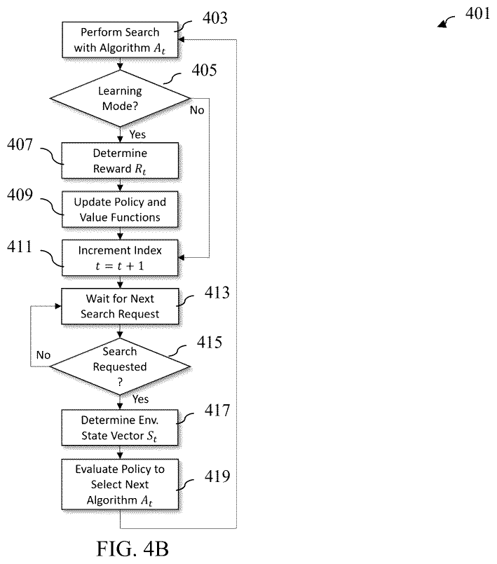

FIG. 4A illustrates exemplary processes 400 and 401 for an autonomous agent (e.g., 212) to output and execute an action, according to some embodiments of the present disclosure. At step 402, the autonomous agent may perform search of a configuration of ISM with search algorithm (e.g., execute action Aₜ). The autonomous agent may execute the search algorithm by applying a control signal corresponding to a configuration of the ISM according to the search algorithm. The execution may be triggered by events detected by the ISM input and output power detectors (e.g., at step 418, where a search request is received based on the input and output power levels of the ISM). When the search algorithm is finished, the autonomous agent may determine whether it is in a learning/training mode at step 404. If yes, process 400 proceeds to step 406. If no, process 400 bypasses the learning mode and proceeds to step 410. At step 406, the autonomous agent may receive a determined reward Rₜ. At step 408, the autonomous agent may update the policy (e.g., 203) and/or value function (e.g., 205). In some embodiments, the decision to enter or bypass learning mode may be communicated from a higher-level management function in the system. In some embodiments, the learning mode may be enabled during a training phase prior to deployment in the field. In some embodiments, in a nonstationary environment, it is beneficial to continue training the autonomous agent in the field.

At step 410, the time index, t, is incremented. Time index t may connect the observed environment state vector Sₜ to the subsequently selected search algorithm Aₜ and received reward Rₜ. After incrementing the time index t, the autonomous agent may determine an environment state vector Sₜ at step 412, and the autonomous agent may evaluate the policy to determine the next search algorithm Aₜ at step 414. In some embodiments, the policy may be deterministic or stochastic. After selecting the next search algorithm, the autonomous agent may wait for a new search request to be triggered by the ISM at step 416. At step 418, if a search request is received, process 400 may proceed to step 402. If no search request is received, process 400 may return to step 416, at which the autonomous agent continues to wait for the next search request.

In some embodiments, the step of waiting for a new search request (e.g., 418) may take an undesirably long period of time, which may be long enough for the environmental state (or environmental state vector) to change. FIG. 4B shows another process 401 in which the steps of determining the environmental state vector and selecting the search algorithm occur immediately after the search request is triggered. Process 401 may incur a computational delay between the search request and search algorithm start, but the delay may be acceptable in some embodiments.

Steps 403-411 may be respectively identical to those of 402-410 of process 400. After incrementing the time index t, the autonomous agent may wait for a new search request to be triggered by the ISM at step 413. At step 415, if a search request is received, process 401 may proceed to step 417. If no search request is received, process 401 may return to step 413, at which the autonomous agent continues to wait for the next search request. After receiving the search request at step 415, the autonomous agent may determine an environment state vector Sₜ at step 417, and the autonomous agent may evaluate the policy to determine the next search algorithm Aₜ at step 419. Process 401 may then proceed to step 403, at which the determined search algorithm Aₜ is performed.

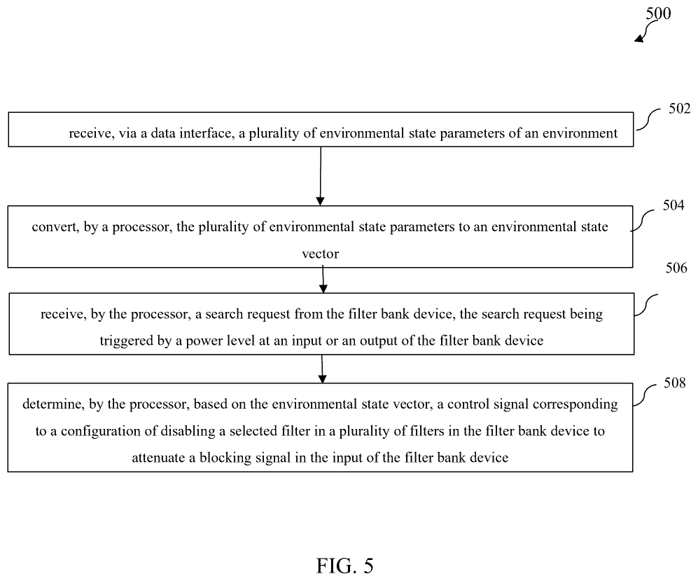

FIG. 5 is a flowchart of a method 500 for a frequency control module to search for the configuration of the filter bank module that blocks a RF signal, according to some embodiments of the present disclosure. Method 500 is merely an example, and is not intended to limit the present disclosure beyond what is explicitly recited in the claims. Additional operations can be provided before, during, and after the method 500, and some operations described can be replaced, eliminated, or moved around for additional embodiments of method 500. For ease of illustration, FIG. 5 is described in connection with FIGS. 1A, 2A, 2B, and 3A.

At step 502, a plurality of environmental state parameters (e.g., 122 and parameters of 204, 206, 208 of FIG. 2A) of an environment are received via a data interface (e.g., 315).

At step 504, the plurality of environmental state parameters are converted to an environmental state vector (Sₜ of FIG. 2A) by a processor (e.g., 310).

At step 506, a search request (e.g., 126) from the filter bank device is received by the processor. The search request is triggered by a power level at an input and/or or an output of the filter bank device.

At step 508, based on the environmental state vector, a control signal (e.g., 124) corresponding to a configuration of disabling a selected filter in a plurality of filters in the filter bank device is determined by the processor, to attenuate a strong signal in the input of the filter bank device.

Those skilled in the art will recognize improvements and modifications to the preferred embodiments of the present disclosure. All such improvements and modifications are considered within the scope of the concepts disclosed herein and the claims that follow.

What is claimed is:

1. A frequency control device, configured to:
receive a plurality of environmental state parameters of an environment; and
convert the plurality of environmental state parameters to an environmental state vector;
receive the environmental state vector and a search request from a filter bank device communicatively coupled to the frequency control device, the search request being triggered by a power level of a radio frequency (RF) signal at an input or an output of the filter bank device; and
determine, based on the environmental state vector, a control signal corresponding to a configuration of disabling a selected filter in a plurality of filters in the filter bank device to attenuate the RF signal in the input of the filter bank device.

2. The frequency control device of claim 2, wherein the determining of the control signal comprises:
selecting a filter-searching algorithm from a plurality of filter-searching algorithms based on the environmental state vector;
applying a search control signal corresponding to a potential configuration of the filter bank device according to the selected filter-searching algorithm; and
in response to a power level of an output of the filter bank device falls below a predetermined value, determining the search control signal to be the control signal.

3. The frequency control device of claim 2, further comprising a power sensor that detects the power level of the output or the input of the filter bank device.

4. The frequency control device of claim 1, wherein the filter bank device comprises an intrinsically switched multiplexing filter.

5. The frequency control device of claim 1, wherein the plurality of environmental state parameters comprise one or more of:
an input power level of the filter bank device;
an output power level of the filter bank device;
a number of enabled filters in the filter bank device;
a number of disabled filters in the filter bank device;
a current of a low-noise amplifier (LNA) coupled to an output of the filter bank device;
a voltage of the LNA;
a bias configuration of the LNA;
an integrated power level of a baseband detector coupled to an output of the LNA;
a DC power level of the baseband detector;
a time domain statistic value of the baseband detector; or
a frequency domain statistic value of the baseband detector.

6. The frequency control device of claim 5, further comprises a plurality of sensors that measure the plurality of environmental state parameters.

7. The frequency control device of claim 1, further comprises a reinforcement learning (RL) model stored in a memory.

8. The frequency control device of claim 7, wherein the RL model is pre-trained.

9. The frequency control device of claim 1, wherein the search request is received after converting the plurality of environmental state parameters to the environmental state vector.

10. The frequency control device of clam 1, wherein the search request is received before converting the plurality of environmental state parameters to the environmental state vector.

11. The frequency control device of claim 7, wherein a training of the RL model comprises:
determining, by the RL model, an action that comprises selecting a filter-searching algorithm from a plurality of filter-searching algorithms, based on a policy and the environmental state vector;
executing the action by performing the selected filter-searching algorithm that incurs a reward;
receiving the reward based on the action; and
updating the policy and a value function based at least on the reward.

12. The frequency control device of claim 7, wherein the RL model comprises a neural network (NN) model.

13. The frequency control device of claim 11, wherein the policy comprises one of a deterministic function or a stochastic function.

14. The frequency control device of claim 11, wherein the value function comprises a set of tabular memory.

15. The frequency control device of claim 11, wherein the updating of the policy and the value function comprises:
computing a difference between the reward and the value function; and
updating the policy and the value function based on the difference.

16. The frequency control device of claim 11, wherein the reward comprises a combination of:
a number of filters enabled when the selected filter-searching algorithm is performed;
a number of state values of the filter bank device attempted by the selected filter-searching algorithm; or
a penalty value for the selected filter-searching algorithm not finding the set of training state values of the filter bank device corresponding to the target wavelength.

17. The frequency control device of claim 5, wherein
the environmental state vector includes no more than two of the plurality of environmental state parameters;
the value function comprises a set of tabular memory data; and
the policy comprises a stochastic function.

18. A method for attenuating a signal at an input of a filter bank device having a plurality of frequency passbands, comprising:
receiving, via a data interface, a plurality of environmental state parameters of an environment;
converting, by a processor, the plurality of environmental state parameters to an environmental state vector; and
receiving, by the processor, a search request from the filter bank device, the search request being triggered by a power level at an input or an output of the filter bank device; and
determining, by the processor, based on the environmental state vector, a control signal corresponding to a configuration of disabling a selected filter in a plurality of filters in the filter bank device to attenuate a radio frequency (RF) signal in the input of the filter bank device.

19. The method of claim 18, wherein the determining of the control signal comprises:
selecting, by a reinforcement learning (RL) model, a filter-searching algorithm from a plurality of filter-searching algorithms based on the environmental state vector;
applying, by the processor, a search control signal corresponding to a potential configuration of the filter bank device according to the selected filter-searching algorithm; and
in response to a power level of an output of the filter bank device falls below a predetermined value, determining, by the processor, the search control signal to be the control signal.

20. A signal attenuation device, comprising:
a filter bank device comprising a plurality of filters corresponding to a plurality of frequency passbands, configured to receive a radio frequency (RF) signal; and
a frequency control device communicatively coupled to the filter bank device, configured to:
receive a plurality of environmental state parameters of an environment;
convert the plurality of environmental state parameters to an environmental state vector; and
determine, based on the environmental state vector, a control signal corresponding to a configuration of disabling a selected filter in a plurality of filters in the filter bank device to attenuate the RF signal in the input of the filter bank device.
